(19) United States
(12) Patent Application Publication
(10) Pub. No.: US 2010/0200853 A1
(43) Pub. Date: Aug. 12, 2010

(54) SEMICONDUCTOR DEVICE AND MANUFACTURING METHOD THEREOF

(75) Inventor: Hideki MISAWA, Sakata (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/687,939

(22) Filed: Jan. 15, 2010

(30) Foreign Application Priority Data
Feb. 10, 2009 (JP) 2009-028536

(51) Int. Cl. H01L 23/544; H01L 21/66

(52) U.S. Cl. 257/48; 438/5; 257/E23.179; 257/E21.521

(57) ABSTRACT

A method for manufacturing a semiconductor device includes: (a) performing an inspection using an evaluation element formed on a scribe line of a semiconductor wafer; (b) marking a character on the semiconductor wafer, the character representing information based on a result obtained in step (a); and (c) performing a step subsequent to step (b) while using the information represented by the character marked in step (b).

The entire disclosure of Japanese Patent Application No. 2009-028536, filed Feb. 10, 2009 is expressly incorporated by reference herein.

### BACKGROUND

1. Technical Field

The present invention relates to a semiconductor device and a manufacturing method thereof and, in particular, to a semiconductor device that is allowed to use, in a probe inspection step, an assembly step, or the like, information or the like obtained in and after a process, and a manufacturing method thereof

2. Related Art

Typically, a wafer ID including alphanumeric character strings is marked on a semiconductor wafer for the purpose of process control, quality control, or the like in the process of manufacturing a semiconductor integrated circuit device. Such a mark is put by engraving a surface of a semiconductor wafer so that the semiconductor wafer withstands high-temperature treatment, such as impurity diffusion or thermal oxidation, in the semiconductor device manufacturing process and is not contaminated.

Typically, a wafer ID is marked on a semiconductor wafer before the semiconductor circuit forming process. Subsequently, a semiconductor integrated circuit including transistors, wiring lines, and the like is formed on the semiconductor wafer through a typical semiconductor circuit forming process including a photolithography step, an etching step, an ion implantation step, and a thin film forming step.

However, the shape of a recess (dot) formed by engraving the surface of the semiconductor wafer becomes bad through the semiconductor circuit forming process. This makes it difficult to identify the wafer ID visually in the probe inspection step, assembly step, and the like that are performed after the semiconductor circuit forming process and in which the semiconductor wafer must be controlled visually.

In order to solve the above-mentioned problem, a second wafer ID having high legibility is marked on the semiconductor wafer after a semiconductor circuit is completed. This makes it possible to control the wafer visually using the second wafer ID in the probe inspection step, assembly step, and the like subsequent to the semiconductor circuit forming process (for example, see JP-A-2005-166885 (paragraphs [0009] to [0016])).

FIG. 10 is a drawing showing a semiconductor wafer 100 formed in such a manner that semiconductor device chips are arranged thereon and shows a semiconductor circuit forming area 101 including a semiconductor element and a wafer ID marking area 102. FIG. 11 is a sectional view showing a mark indicating a wafer ID according to the related-art.

As shown in FIG. 10, a wafer ID is marked on the wafer ID marking area 102 before forming a semiconductor circuit including transistors and the like. The wafer ID is marked by making a recess by applying a laser beam to a surface of the semiconductor wafer directly. The wafer ID includes alphanumeric character strings. For example, as shown in FIG. 11, the wafer ID includes 15 characters. The wafer ID is marked while forming a character group “a” indicating information indicating the type of the semiconductor device, a character group “b” indicating the lot number, a character group “c” indicating the wafer number, and a character group “d” indicating a check number for reading the wafer ID.

Even if the second wafer ID having high legibility is marked after forming a semiconductor circuit, information obtained in and after a process cannot be determined from the marked wafer second ID. Also, the above-mentioned information cannot be used in any of the probe inspection step, assembly step, and the like.

### SUMMARY

An advantage of the invention is to provide a semiconductor device that is allowed to use, in a probe inspection step, an assembly step, and the like, information obtained in and after a process, and a manufacturing method thereof.

A method for manufacturing a semiconductor device according to a first aspect of the invention includes: (a) performing an inspection using an evaluation element formed on a scribe line of a semiconductor wafer; (b) marking a character on the semiconductor wafer, the character representing information based on a result obtained in step (a); and (c) performing a step subsequent to step (b) while using the information represented by the character marked in step (b).

In the above-mentioned semiconductor device manufacturing method, a character representing the information based on the result obtained in step (a) is marked on the semiconductor wafer, and the step subsequent to step (b) is performed while using the information represented by the character marked in step (b). This makes it possible to perform a semiconductor device probe inspection or an assembly step while using the information as a rank identification mark. Thus, a yield increase effect, a manufacturing cost reduction effect, and the like are obtained.

A method for manufacturing a semiconductor device according to a second aspect of the invention includes: (a) processing a semiconductor wafer; (b) inspecting a size of a product obtained by processing the semiconductor wafer; (c) marking a character on the semiconductor wafer, the character representing information based on a result obtained in step (b); and (d) performing a step subsequent to step (c) while using the information represented by the character marked in step (c).

In the method for manufacturing a semiconductor device according to the first aspect of the invention, step (b) may be a step where the semiconductor wafer closer to a standard value is ranked more highly on the basis of a result obtained in step (a) and where a character representing information indicating the ranking is marked on the semiconductor wafer.

In the method for manufacturing a semiconductor device according to the first aspect of the invention, step (c) is preferably one of a probe inspection step and an assembly step.

In the method for manufacturing a semiconductor device according to the first aspect of the invention, if the information represented by the character is information indicating the semiconductor wafer ranked more highly in the ranking due to being closer the standard value, the probe inspection step may be a step of performing a probe inspection using a simple probe inspection program.

In the method for manufacturing a semiconductor device according to the first aspect of the invention, if the information represented by the character is information indicating the semiconductor wafer ranked more lowly in the ranking due to being more distant from the standard value, the probe inspection step may be a step of performing a probe inspection using an auxiliary probe inspection program.

In the method for manufacturing a semiconductor device according to the first aspect of the invention, if the information represented by the character is information indicating the semiconductor wafer ranked more highly in the ranking due to being closer to the standard value, the semiconductor device is preferably assembled in the assembly step as a first product that is required to have high quality. Also, if the information represented by the character is information indicating the semiconductor wafer ranked more lowly in the ranking due to being more distant from the standard value, the semiconductor device is preferably assembled in the assembly step as a second product that is required to have quality lower than quality of the first product.

A semiconductor device manufacturing method according to a third aspect of the invention includes: (a) performing an inspection using an evaluation element formed on a scribe line of a semiconductor wafer; and (b) performing a step subsequent to step (a) while using information based on a result obtained in step (a).

A semiconductor device manufacturing method according to a fourth aspect of the invention includes: (a) processing a semiconductor wafer; (b) inspecting a size of a product obtained by processing the semiconductor wafer; and (c) performing a step subsequent to step (b) while using information based on a result obtained in step (b).

In the method for manufacturing a semiconductor device according to the third aspect of the invention, the information is preferably information indicating ranking where the semiconductor wafer closer to a standard value is ranked more highly on the basis of a result obtained in step (b).

In the method for manufacturing a semiconductor device according to the third aspect of the invention, step (c) is preferably one of a probe inspection step and an assembly step.

In the method for manufacturing a semiconductor device according to the third aspect of the invention, if the information is information indicating the semiconductor wafer ranked more highly in the ranking due to being closer the standard value, the probe inspection step may be a step of performing a probe inspection using a simple probe inspection program.

In the method for manufacturing a semiconductor device according to the third aspect of the invention, if the information is information indicating the semiconductor wafer ranked more lowly in the ranking due to being more distant from the standard value, the probe inspection step may be a step of performing a probe inspection using an auxiliary probe inspection program.

In the method for manufacturing a semiconductor device according to the third aspect of the invention, if the information is information indicating the semiconductor wafer ranked more highly in the ranking due to being closer to the standard value, the semiconductor device is preferably assembled in the assembly step as a first product that is required to have high quality. Also, if the information is information indicating the semiconductor wafer ranked more lowly in the ranking due to being more distant from the standard value, the semiconductor device is preferably assembled in the assembly step as a second product that is required to have quality lower than quality of the first product.

A semiconductor device according to a fifth aspect of the invention includes: an evaluation element formed on a scribe line of a semiconductor wafer; and a character marked on the semiconductor wafer, the character representing information based on an inspection result obtained by performing an inspection using the evaluation element, the information being used in one of a probe inspection process and an assembly step.

A semiconductor device according to a sixth aspect of the invention includes: a product formed on a semiconductor wafer by processing the semiconductor wafer; and a character marked on the semiconductor wafer, the character representing information based on an inspection result obtained by inspecting a size of the product, the information being used in one of a probe inspection process and an assembly step.

### BRIEF DESCRIPTION OF THE DRAWINGS

The invention will be described with reference to the accompanying drawings, wherein like reference numerals represent like elements.

FIG. 1 is a sectional view showing a semiconductor device according to a first embodiment of the invention.

FIG. 2 is a sectional view showing a semiconductor device according to a second embodiment of the invention.

FIG. 3 is a drawing showing a semiconductor wafer according to the embodiments of the invention.

FIG. 4 is a drawing showing a mark indicating a wafer ID according to the embodiments of the invention.

FIG. 5 is a graph schematically showing a control criterion with respect to the semiconductor wafer.

FIG. 6 is a flowchart showing the timing when a mark indicating a wafer ID is put on a surface of the semiconductor wafer according to the first embodiment of the invention.

FIG. 7 is a flowchart showing the timing when a mark indicating a wafer ID is put on a surface of the semiconductor wafer according to the second embodiment of the invention.

FIG. 8 is a flowchart showing the timing when a mark indicating a wafer ID is put on a surface of the semiconductor wafer according to a third embodiment of the invention.

FIG. 9 is a flowchart showing the timing when a mark indicating a wafer ID is put on a surface of the semiconductor wafer according to a fourth embodiment of the invention.

FIG. 10 is a drawing showing a related-art semiconductor wafer.

FIG. 11 is a drawing showing a mark indicating a wafer ID according to the related art.

### DESCRIPTION OF THE PREFERRED EMBODIMENTS

Now, embodiments of the invention will be described with reference to the accompanying drawings.

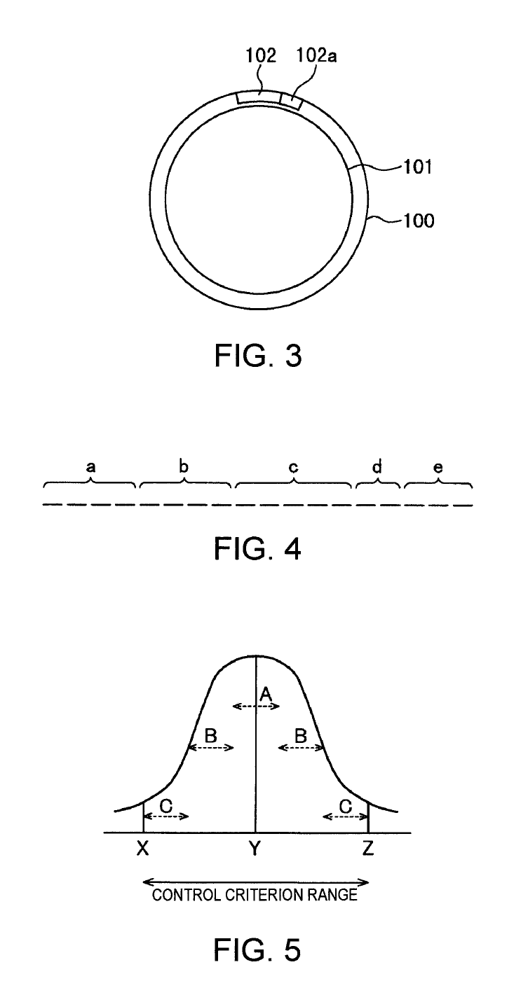

FIG. 3 is a drawing showing a semiconductor wafer according to first to fourth embodiments of the invention and shows a semiconductor wafer 100 formed in such a manner that semiconductor device chips are arranged thereon and shows a semiconductor circuit formation area 101 including a semiconductor element, a wafer ID marking area 102, and an additional marking area 102a. FIG. 4 is a drawing showing a mark indicating a wafer IC and is a drawing showing a wafer IC marked on the wafer ID marking area 102 and additional marking area 102a shown in FIG. 3.

### First Embodiment

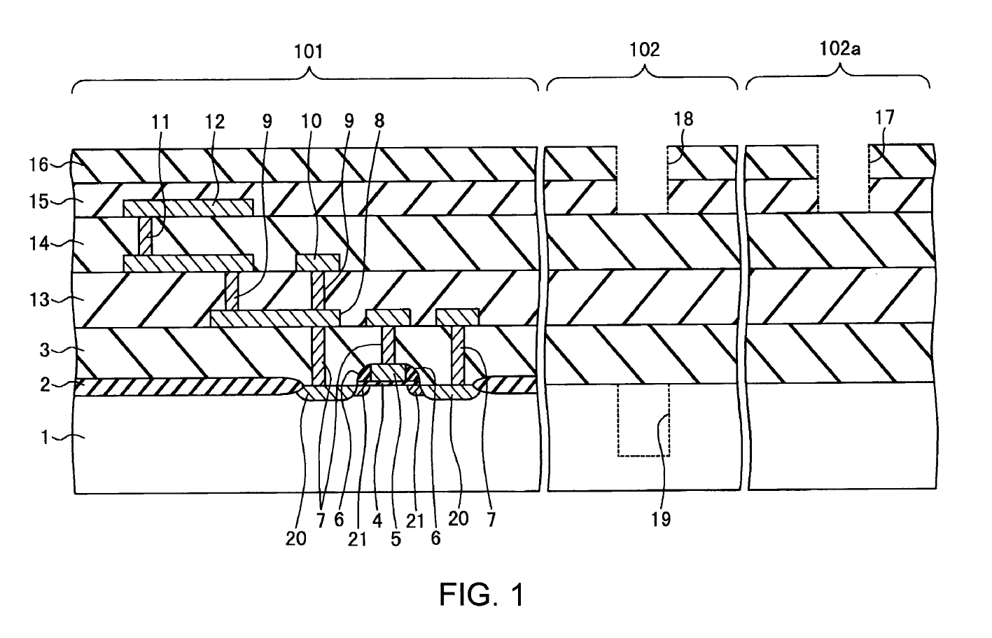

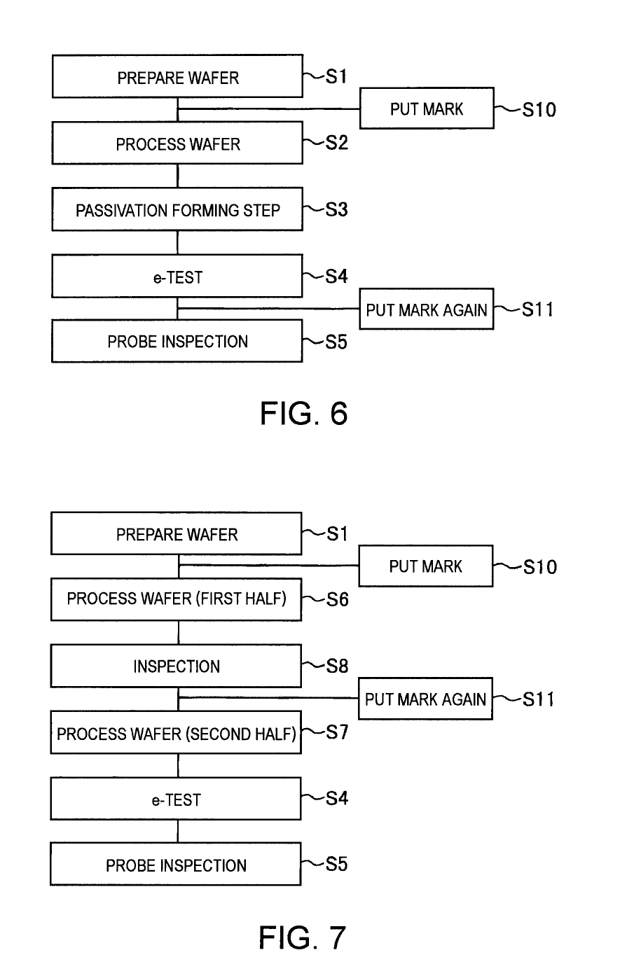

FIG. 1 shows a semiconductor device according to the first embodiment of the invention and is a sectional view partially showing the semiconductor circuit formation area 101, wafer ID marking area 102, and additional marking area 102a shown in FIG. 3. FIG. 6 is a flowchart showing the timing when a wafer ID is marked on a surface of a semiconductor wafer according to the first embodiment of the invention.

First, a semiconductor wafer on which a semiconductor circuit has yet to be formed is prepared (S1). Next, as shown in FIGS. 1 and 3, a laser beam is applied to a silicon substrate 1 inside the wafer ID marking area 102. Thus, a recess 19 is made so that a mark is put (S10). At that time, character groups “a,” “b,” “c,” and “d” are marked on the wafer ID marking area 102 as shown in FIG. 4. The character group “a” is formed by an alphanumeric character string indicating the type of the semiconductor device, and the like. The character group “b” is formed by an alphanumeric character string representing the lot number, and the like. The character group “c” is formed by an alphanumeric character string representing the wafer number, and the like. The character group “d” is formed by an alphanumeric character string representing the check number for reading a wafer ID, and the like.

Subsequently, the semiconductor circuit formation area 101 is subjected to wafer processing so as to form a semiconductor circuit (S2). This wafer processing will be described with reference to FIG. 1. First, a LOCOS oxide film 2 serving as an element separation film is formed on a surface of the silicon substrate 1. Next, a gate oxide film to serve as a gate insulating film 4 is formed on the surface of the silicon substrate 1 by thermal oxidation. Subsequently, a polysilicon film is formed on the gate insulating film 4 and LOCOS oxide film 2 by CVD (chemical vapor deposition) and then processed by photolithography and dry etching. Thus, a gate electrode 5 is formed on the gate insulating film 4.

Next, impurity ions are implanted in the silicon substrate 1 using the gate electrode 5 and LOCOS oxide film 2 as masks so that a LDD area 21, which is a low-concentration impurity layer, is formed. Next, for example, a silicon nitride film is formed on the entire surface of the substrate including the gate electrode 5 and LOCOS oxide film 2 by CVD. Subsequently, the silicon nitride film is etched by etch back so that a sidewall 6 is formed on the side wall of the gate electrode 5. Next, impurity ions are implanted in the silicon substrate 1 using the gate electrode 5, sidewall 6, and LOCOS oxide film 2 as masks and then thermal treatment is performed on the silicon substrate 1. Thus, a diffusion layer is formed in a source/drain area 20 in a self-alignment manner.

Next, a first inter-layer insulating film 3 is formed on the entire surface of the substrate including the gate electrode 5, sidewall 6, and LOCOS oxide film 2 by CVD. Subsequently, holes are made on the first inter-layer insulating film 3. Next, a metallic film is formed inside the holes and on the first inter-layer insulating film 3 by sputtering. Subsequently, the metallic film on the first inter-layer insulating film 3 is eliminated by CMP. Thus, first plugs 7 electrically connected to the source/drain area 20 and gate electrode 5 are formed on the first inter-layer insulating film 3. Subsequently, a wiring layer is formed on the first inter-layer insulating film 3 and first plugs 7 by sputtering and then processed by photolithography and dry etching so that a first wiring line 8 made of a wiring layer is formed.

Subsequently, a second inter-layer insulating film 13 is formed on the first inter-layer insulating film 3 and first wiring line 8 by CVD. Subsequently, holes are made on the second inter-layer insulating film 13. Next, a metallic film is formed inside the holes and on the second inter-layer insulating film 13 by sputtering. Subsequently, the metallic film on the second inter-layer insulating film 13 is eliminated by CMP. Thus, second plugs 9 electrically connected to the first wiring line 8 are formed on the second inter-layer insulating film 13. Subsequently, a wiring layer is formed on the second inter-layer insulating film 13 and second plugs 9 by sputtering and then processed by photolithography and dry etching so that a second wiring line 10 made of the wiring layer is formed.

Subsequently, a third inter-layer insulating film 14 is formed on the second inter-layer insulating film 13 and second wiring line 10 by CVD. Subsequently, a hole is made on the third inter-layer insulating film 14. Next, a metallic film is formed inside the hole and on the third inter-layer insulating film 14 by sputtering. Subsequently, the metallic film on the third inter-layer insulating film 14 is eliminated by CMP. Thus, a third plug 11 electrically connected to the second wiring line 10 is formed on the third inter-layer insulating film 14. Subsequently, a wiring layer is formed on the third inter-layer insulating film 14 and third plug 11 by sputtering and then processed by photolithography and dry etching so that a third wiring line 12 made of the wiring layer is formed.

Subsequently, a passivation film made up of a silicon oxide film 15 and a silicon nitride film 16 is formed on the third inter-layer insulating film 14. Next, the passivation film is processed by photolithography and dry etching (S3). In this case, the passivation film may be formed of a single layer of silicon oxide film or a single layer of silicon nitride film.

Next, a semiconductor device property inspection (e-TEST) is performed on the semiconductor wafers, which have undergone wafer processing, using a TEG that is formed on a scribe line and is an evaluation element for finding a design problem, a manufacturing problem, or the like (S4). The semiconductor wafers are each ranked in accordance with the properties of the semiconductor device on the basis of the result of the e-TEST. For example, a graph shown in FIG. 5 is a graph schematically showing a control criterion with respect to semiconductor wafers. Using the Y value as the standard value, the range from the X value to the Z value is defined as the control criterion range. Products are ranked: products included in a range A closest to the standard value are ranked as A; products included in a B range second closest thereto are ranked as B; and products included in a range C most distant therefrom are ranked as C. By ranking products having better properties as A, B, and C as described above, the method for performing a probe inspection (SORT) (S5) that is the subsequent step and in which the product properties of the semiconductor device are inspected can be changed or the shipping destination can be changed.

In a specific example 1 of the above-mentioned e-TEST, a Vth property, which is the threshold voltage of a transistor, is measured. In a specific example 2, an Idsat property, which is the drive current of the transistor is measured. In a specific example 3, the resistance value property of a conductor including the wiring layer, plug connection, gate wiring line, and the like is measured. In a specific example 4, the Qbd property for examining the quality of the gate oxide film is measured. From these measurement results, the semiconductor wafers are ranked in accordance with the ranges A, B, and C that correspond to the measurements and are shown in FIG. 5. Such ranking is performed by a computer (not shown).

Next, as shown in FIG. 1, a laser beam is applied to the passivation film, which is a multilayer film of the silicon oxide film 15 and silicon nitride film 16, in the marking area 102 and additional marking area 102a. Thus, a recess 18 is made on the wafer ID marking area 102 so that the wafer ID is marked again, and a recess 17 is made on the additional marking area 102a shown in FIG. 3 so that a mark is put (S11). In this case, the mark on the additional marking area 102a is formed as a character group “e” shown in FIG. 4 on the side of the character groups on the wafer ID marking area 102. Information obtained by ranking the semiconductor wafers in accordance with the properties of the semiconductor device on the basis of the result of the e-TEST is marked on the additional marking area 102a.

Next, the semiconductor wafers ranked in accordance with the properties of the semiconductor device on the basis of the result of the e-TEST are subjected to a semiconductor device probe inspection (SORT) using the information marked on the additional marking area 102a as a rank identification mark (S5).

In the probe inspection (S5), products having information indicating rank A marked on the additional marking area 102a on the basis of the result of the e-TEST are products closer to the standard value and are considered as having good properties and are then subjected to a probe inspection using a simplified probe inspection program. Products having information indicating rank B marked on the additional marking area 102a on the basis of the result of the e-TEST are considered as averagely finished products and are then subjected to a probe inspection using a normal probe inspection program. Products having information indicating rank C marked on the additional marking area 102a on the basis of the result of the e-TEST are products most distant from the standard value and are considered as having poor properties and must be inspected carefully. For this reason, a probe inspection is performed using an auxiliary probe inspection program different from a normal probe inspection program. Subsequently, a product assembly step is performed. In the assembly step, rank-A semiconductor wafers may be assembled, for example, as products for a car-mounted purpose or the like that are required to have high quality, rank-B semiconductor wafers may be assembled as products that are required to have medium quality, and rank-C semiconductor wafers may be assembled as products that are required to have low quality.

As seen, in the first embodiment of the invention, information indicating ranking of the semiconductor wafer in accordance with the properties of the semiconductor device on the basis of the result of the e-TEST is marked on the additional marking area 102a. Then, using the information as a rank identification mark, a probe inspection (SORT) is performed on the semiconductor device or assembly step is performed. Thus, a yield increase effect, a manufacturing cost reduction effect, and the like are obtained.

### Second Embodiment

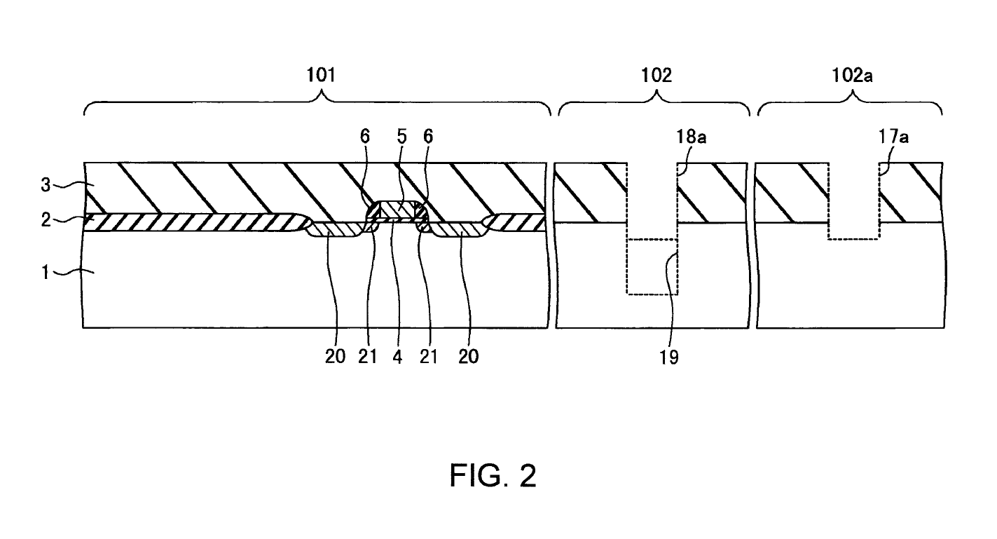

Next, a method for manufacturing a semiconductor device according to a second embodiment of the invention will be described. FIG. 2 shows the semiconductor device according to the second embodiment of the invention and is a sectional view partially showing the semiconductor circuit formation area 101, wafer ID marking area 102, and additional marking area 102a shown in FIG. 3. FIG. 7 is a flowchart showing the timing when a wafer ID is marked on a surface of the semiconductor wafer according to the second embodiment of the invention.

First, a wafer is prepared (S1) and a mark is put thereon (S10) using the method used in the first embodiment. The subsequent steps for processing the wafer to form a semiconductor circuit until the step of forming a diffusion layer of the source/drain area 20 in the semiconductor circuit formation area 101 are the same as those of the first embodiment and will not be described. The steps until the step of forming a diffusion layer of the source/drain area 20 will be referred to as a wafer processing first half process (S6), and the subsequent manufacturing steps will be referred to as a wafer processing second half process (S7).

The semiconductor wafers that have undergone the wafer processing first half process (S6) are subjected to an inspection (S8). The semiconductor wafers are ranked on the basis of the inspection result. As the ranking method, for example, that shown in FIG. 5 and described in the first embodiment is used.

In a specific example 1 of the above-mentioned check (S8), the size of the gate electrode is measured. In a specific example 2 thereof, the thickness of the gate oxide film is measured. In a specific example 3 thereof, whether there has been a trouble before the wafer processing first half process is checked. Among troubles that may occur are troubles, such as a mask change made to correct a bug that has been found when mass-producing products and a device-related trouble. The semiconductor wafers are ranked in accordance with the size standard thereof on the basis of the control criterion shown in the graph of FIG. 5 using the measurement results in the specific examples 1 and 2. Also, the semiconductor wafers are ranked in accordance with the significance of a trouble using the check result in the specific example 3. Such ranking is performed by a computer (not shown).

Next, as shown in FIG. 2, the first inter-layer insulating film 3 is formed on the entire surface of the substrate including the gate electrode 5, sidewall 6, and LOCOS oxide film 2 by CVD. Subsequently, a laser beam is applied to the first inter-layer insulating film 3 in the wafer ID marking area 102 and additional marking area 102a. Thus, a recess 18a is made on the wafer ID marking area 102 so that the wafer ID is marked again, and a recess 17 is made on the additional marking area 102a so that a mark is put (S11). In this case, the mark on the additional marking area 102a is formed as the character group “e” shown in FIG. 4 on the side of the character groups on the wafer ID marking area 102. The mark put on the additional marking area 102a represents information indicating the result of the ranking performed on the semiconductor wafer on the basis of the inspection result after the wafer processing first half process. In this embodiment, a mark indicating the ranking information is put on the first inter-layer insulating film 3; however, the mark may be put on another film as long as the another film is a film lower than the passivation film.

The subsequent wafer processing second half process (S7), where the wafer is processed until a passivation film is formed, is the same as that of the first embodiment and will not be described. The wafer processing second half process (S7) is performed using the mark, which is put on the additional marking area 102a and indicates information, as a rank identification mark (S7). The semiconductor wafers ranked on the basis of the inspection result after the wafer processing second half process will be processed into product types corresponding to the ranks thereof.

More specifically, products having information indicating rank A marked on the additional marking area 102a on the basis of the inspection result after the wafer processing first half process are products closer to the criteria value and are regarded as having good properties and will be processed in the second half process as products for a car-mounted purpose or the like, which are required to have high quality. Products having information indicating rank-B marked on the additional marking area 102a are considered as averagely finished products and will be subjected to the second half process. Product having information indicating rank C marked on the additional marking area 102a are products most distant from the standard value and are considered as products having poor properties. Rank-C products include products that have caused a trouble. If a rank-C product is considered as a defective product, it is necessary to put a mark for identifying a defective product on the rank-C product using ink and then remove the rank-C product in later steps.

Next, the semiconductor wafers, which have undergone the wafer processing, are subjected to a semiconductor device property inspection (e-TEST) using a TEG, which is formed on a scribe line and is an evaluation element for finding a design problem or a manufacturing problem (S4).

Subsequently, a semiconductor device probe inspection (SORT) is performed (S5). The probe inspection may be performed on the rank-A products, rank-B products, and rank-C products ranked on the basis of the inspection results in the specific examples 1 to 3, using the method used in the first embodiment. For example, rank-A products are subjected to a probe inspection using a simple probe inspection program, rank-B products are subjected to a probe inspection using a normal probe inspection program, and rank-C products are subjected to a probe inspection using an auxiliary probe inspection program different from the normal probe inspection program. Subsequently, a product assembly step is performed.

As seen, in the second embodiment of the invention, the information indicating the result of ranking performed on the basis of the result of the inspection (S8) is marked on the additional marking area 102a. Then, using the information, the wafer processing second half process (S7), the probe inspection (SORT) of the semiconductor device, and assembly step are performed. Thus, a yield increase effect, a manufacturing cost reduction effect, and the like are obtained.

### Third Embodiment

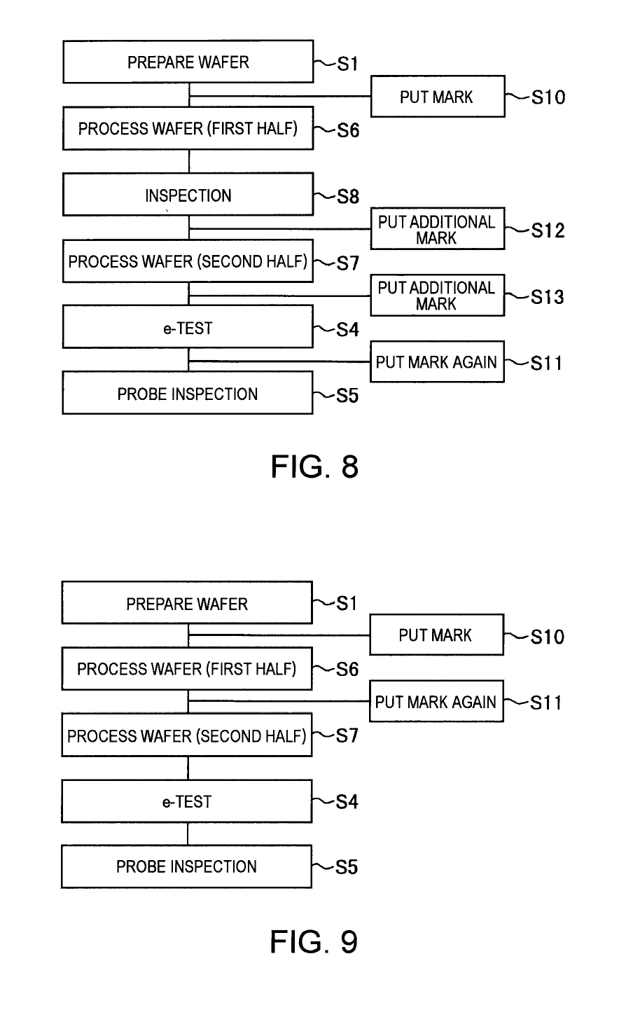

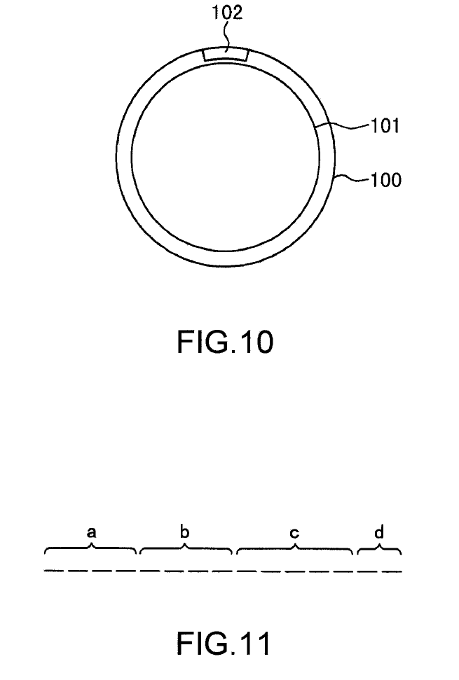

Next, a method for manufacturing a semiconductor device according to a third embodiment of the invention will be described. FIG. 8 is a flowchart showing the timing when a wafer ID is marked on a surface of the semiconductor wafer according to the third embodiment of the invention. The same parts of the semiconductor circuit formation process as those of the first embodiment will not be described.

First, a wafer is prepared (S1) and a mark is put thereon (S10) using the method used in the first embodiment. The subsequent steps for processing the wafer to form a semiconductor circuit until the step of forming a diffusion layer of the source/drain area 20 in the semiconductor circuit formation area 101 are the same as those of the first embodiment and will not be described. The steps until the step of forming a diffusion layer of the source/drain area 20, of the wafer processing process will be referred to as a wafer processing first half process (S6), and the subsequent manufacturing steps will be referred to as a wafer processing second half process (S7).

Next, after the wafer processing first half process (S6) is completed, an inspection (S8) is performed, and the semiconductor wafers are ranked on the basis of the result of the inspection. The inspection (S8) and ranking are performed as in the second embodiment and will not be described.

Next, the first inter-layer insulating film 3 is formed using the method used in the second embodiment and then an additional mark is put on the first inter-layer insulating film 3 in the additional marking area 102a (S12). Subsequently, the wafer processing second half process (S7), where the wafer is processed until a passivation film is formed, is performed using the method used in the second embodiment and using the ranks.

Subsequently, the semiconductor wafers, which have undergone the wafer processing second half process (S7), are ranked on the basis of whether there has been a trouble when performing the wafer processing second half process. For example, the semiconductor wafers are ranked on the basis of the significance of a trouble. Among troubles that may occur when processing the wafers are troubles, such as a mask change to correct a bug that has found when mass-producing a product and a device-related trouble. The ranking is performed by a computer (not shown).

Next, a laser beam is applied to the passivation film, which is a multilayer film of the silicon oxide film 15 and silicon nitride film 16, in the additional marking area 102a. Thus, the recess 19 is made on the additional marking area 102a shown in FIG. 3 so that a mark is put (S13). In this case, the mark is put on the additional marking area 102a as the character group “e” shown in FIG. 4 on the side of the character groups on the wafer ID marking area 102. Also, the mark put on the additional marking area 102a represents information indicating the result of ranking performed on the basis of the significance of a trouble caused in the wafer processing second half process.

Next, the semiconductor wafers, which have undergone the wafer processing, are each subjected to a semiconductor device property test (e-TEST) using a TEG, which is formed on a scribe line and is an evaluation element for finding a design or manufacturing problem (S4), and are ranked on the basis of the properties of the semiconductor device on the basis of the result of the e-TEST. The ranking is performed as in the first embodiment.

Next, the wafer ID is marked again on the passivation film in the wafer ID marking area 102 using the method used in the first embodiment, and an additional mark is put on the passivation film in the additional marking area 102a (S11).

Next, a semiconductor device probe inspection (SORT) is performed using the method used in the first embodiment and using the information marked on the additional marking area 102a as a rank identification mark (S5).

In the probe inspection (S5), the rank identification mark is used using the method used in the first embodiment. Rank-C products include products that have caused a trouble in the wafer processing process. If a rank-C product is considered as a defective product, it is necessary to put a mark for identifying a defective product on the rank-C product using ink and then remove the rank-C product in later steps. Subsequently, a product assembly step is performed.

As seen, the third embodiment of the invention can also obtain the same advantages as those of the first and second embodiments.

### Fourth Embodiment

Next, a method for manufacturing a semiconductor device according to a fourth embodiment of the invention will be described. FIG. 9 is a flowchart showing the timing when a wafer ID is marked on a surface of a semiconductor wafer.

First, a wafer is prepared (S1) and a mark is put thereon (S10) using the method used in the first embodiment. The subsequent wafer processing process for forming a semiconductor circuit until the step of forming a diffusion layer of the source/drain area 20 in the semiconductor circuit formation area 101 is the same as that of the first embodiment and will not be described. The steps of the wafer processing process until the step of forming a diffusion layer of the source/drain area 20 will be referred to as a wafer processing first half process (S6), and the subsequent manufacturing steps will be referred to as a wafer processing second half process (S7).

The same steps are performed until the wafer processing first half process (S6) is completed, regardless of what type of product will be manufactured. On the other hand, in the wafer processing second half process (S7), different manufacturing steps are performed depending on the product type or a request from the shipping destination of the product. For example, the mask of the wiring layer and the number of mask sets are changed depending on the product type or a request from the shipping destination of the product. For this reason, the wafer processing process is divided into the first half process (S6) and the second half process (S7).

Next, the first inter-layer insulating film 3 is formed using the method used in the second embodiment. Subsequently, a laser beam is applied to the first inter-layer insulating film 3 in the wafer ID marking area 102 and additional marking area 102a so that the wafer ID is marked again on the wafer ID marking area 102. Also, a mark is put on the additional marking area 102a (S11). The mark put on the additional marking area 102a indicates information for identifying the wafer processing second half process that is changed depending on the product type or a request from the shipping destination of the product.

The subsequent wafer processing second half process (S7), where the semiconductor wafer is processed until a passivation film is formed, is the same as that of the first embodiment and will not be described. The wafer processing second half process is performed using the information marked on the additional marking area 102a (S7). Thus, the semiconductor wafers are processed into corresponding product types without making a mistake in changing the mask of the wiring layer or in the number of mask sets or the like.

Next, the semiconductor wafers, which have undergone the wafer processing, are subjected to a semiconductor device property test (e-TEST) using a TEG, which is formed on a scribe line and is an evaluation element for finding a design or manufacturing problem (S4). Subsequently, the semiconductor device probe inspection (SORT) is performed (S5). At that time, an e-TEST and a probe inspection corresponding to each product type are performed using the information marked on the additional marking area 102a. Subsequently, a product assembly step is performed.

As seen, in the fourth embodiment of the invention, the information for identifying the wafer processing second half process that is changed depending on the product type or a request from the shipping destination of the product is marked on the additional marking area 102a. This makes it possible to use the marked information in the wafer processing second half process (S7).

The invention is not limited to the above-mentioned embodiments and various changes can be made thereto without departing from the spirit and scope of the invention.

In the above-mentioned first to fourth embodiments, information obtained in and after a process is marked on a wafer and the marked information is read. Thus, the marked information is used in the wafer processing second process, probe inspection process, assembly process, and the like. However, by causing a computer to store and control information obtained in and after a process in such a manner that the information corresponds to the wafer number, it is possible to use the information in the wafer processing second process, probe inspection process, assembly process, and the like. In this case, the information does not always need to be marked on a wafer.

What is claimed is:

1. A method for manufacturing a semiconductor device, the method comprising:
(a) performing an inspection using an evaluation element formed on a scribe line of a semiconductor wafer;
(b) marking a character on the semiconductor wafer, the character representing information based on a result obtained in step (a); and
(c) performing a step subsequent to step (b) while using the information represented by the character marked in step (b).

2. The method for manufacturing a semiconductor device according to claim 1, wherein
step (b) is a step where the semiconductor wafer closer to a standard value is ranked more highly on the basis of a result obtained in step (a) and where a character representing information indicating the ranking is marked on the semiconductor wafer.

3. The method for manufacturing a semiconductor device according to claim 1, wherein
step (c) is one of a probe inspection step and an assembly step.

4. The method for manufacturing a semiconductor device according to claim 3, wherein
if the information represented by the character is information indicating the semiconductor wafer ranked more highly in the ranking due to being closer the standard value, the probe inspection step is a step of performing a probe inspection using a simple probe inspection program.

5. The method for manufacturing a semiconductor device according to claim 3, wherein
if the information represented by the character is information indicating the semiconductor wafer ranked more lowly in the ranking due to being more distant from the standard value, the probe inspection step is a step of performing a probe inspection using an auxiliary probe inspection program.

6. The method for manufacturing a semiconductor device according to claim 3, wherein
if the information represented by the character is information indicating the semiconductor wafer ranked more highly in the ranking due to being closer to the standard value, the semiconductor device is assembled in the assembly step as a first product that is required to have high quality, and
if the information represented by the character is information indicating the semiconductor wafer ranked more lowly in the ranking due to being more distant from the standard value, the semiconductor device is assembled in the assembly step as a second product that is required to have quality lower than quality of the first product.

7. A method for manufacturing a semiconductor device, the method comprising:
(a) performing an inspection using an evaluation element formed on a scribe line of a semiconductor wafer; and
(b) performing a step subsequent to step (a) while using information based on a result obtained in step (a).

8. The method for manufacturing a semiconductor device according to claim 7, wherein
the information is information indicating ranking where the semiconductor wafer closer to a standard value is ranked more highly on the basis of a result obtained in step (a).

9. The method for manufacturing a semiconductor device according to claim 7, wherein
step (b) is one of a probe inspection step and an assembly step.

10. The method for manufacturing a semiconductor device according to claim 9, wherein
if the information is information indicating the semiconductor wafer ranked more highly in the ranking due to being closer the standard value, the probe inspection step is a step of performing a probe inspection using a simple probe inspection program.

11. The method for manufacturing a semiconductor device according to claim 9, wherein
if the information is information indicating the semiconductor wafer ranked more lowly in the ranking due to being more distant from the standard value, the probe inspection step is a step of performing a probe inspection using an auxiliary probe inspection program.

12. The method for manufacturing a semiconductor device according to claim 9, wherein
if the information is information indicating the semiconductor wafer ranked more highly in the ranking due to being closer to the standard value, the semiconductor device is assembled in the assembly step as a first product that is required to have high quality, and
if the information is information indicating the semiconductor wafer ranked more lowly in the ranking due to being more distant from the standard value, the semiconductor device is assembled in the assembly step as a second product that is required to have quality lower than quality of the first product.

13. A semiconductor device comprising:
an evaluation element formed on a scribe line of a semiconductor wafer; and
a character marked on the semiconductor wafer, the character representing information based on an inspection result obtained by performing an inspection using the evaluation element, the information being used in one of a probe inspection process and an assembly step.
